(19) United States
(12) Patent Application Publication
(10) Pub. No.: US 2025/0274693 A1
(43) Pub. Date: Aug. 28, 2025

(54) EARPIECES WITH CAPACITIVE TOUCH INTERFACES

(71) Applicant: Bose Corporation, Framingham, MA (US)

(72) Inventors: Richmond Andrew Real, Uxbridge, MA (US); Arthur Mistler, Sutton, MA (US); Jay Klemme, Framingham, MA (US)

(73) Assignee: Bose Corporation, Framingham, MA (US)

(21) Appl. No.: 18/589,365

(22) Filed: Feb. 27, 2024

(51) Int. Cl. H04R 1/10

(52) U.S. Cl. CPC H04R 1/1041

(57) ABSTRACT

An earpiece includes a primary capacitive sensor, a secondary capacitive sensor that is arranged substantially orthogonally to the primary capacitive sensor, and a controller that is configured to receive input from the primary capacitive sensor to control one or more functions of the earpiece. The controller is further configured to receive input from the secondary capacitive sensor to detect if there is an interfering contact with the earpiece, and, if so, reject input from the capacitive touch interface.

### BACKGROUND

Some conventional earpieces (e.g., in-ear headphones) utilize capacitive sensing to provide a user interface. However, when the user wearing the buds has wet hair that drapes across the earpieces, or when the user has a hat that is pulled over the earpieces, then the capacitive sensor can misinterpret that interfering contact as user input and respond to it, which can cause frustration for the user.

### SUMMARY

All examples and features mentioned below can be combined in any technically possible way.

In one aspect, an earpiece includes a primary capacitive sensor, a secondary capacitive sensor that is arranged substantially orthogonally to the primary capacitive sensor, and a controller that is configured to receive input from the primary capacitive sensor to control one or more functions of the earpiece. The controller is further configured to receive input from the secondary capacitive sensor to detect if there is an interfering contact with the earpiece, and, if so, reject input from the capacitive touch interface.

Implementations may include one of the following features, or any combination thereof.

In some implementations, the earpiece incudes a housing and the primary capacitive sensor includes one or more primary capacitive sensor electrodes disposed on an inner surface of the housing.

In certain implementations, the earpiece includes a printed circuit board that is disposed within the housing and the secondary capacitive sensor includes one or more secondary capacitive sensor electrodes disposed on a surface of the printed circuit board.

In some cases, the printed circuit board includes a top surface that is arranged substantially parallel to the one or more primary capacitive sensor electrodes, a second surface, opposite the first surface; and an edge surface that extends between the top and bottom surfaces. The one or more secondary capacitive sensor electrodes may be disposed on the edge surface.

In certain cases, one or more spring contacts are mounted on the top surface of the printed circuit board. The one or more spring contacts provide an electrical connection between the one or more primary capacitive sensor electrodes and the printed circuit board.

In some examples, the controller is mounted on the top surface or the bottom surface of the printed circuit board.

In certain examples, the controller is electrically connected to the one or more spring contacts via one or more electrically conductive traces of the printed circuit board.

In some implementations, the one or more secondary capacitive sensor electrodes are formed by plating the surface of the printed circuit board.

In certain implementations, the housing includes a first housing portion, a second housing portion, and a third housing portion. The first housing portion at least partially defines an acoustic module that houses an electro-acoustic transducer. The second housing portion at least partially defines an electronics module that houses electronics for driving the electro-acoustic transducer. The one or more primary capacitive sensor electrodes are disposed on the third housing portion.

In some cases, the secondary capacitive sensor includes one or more secondary capacitive sensor electrodes disposed on a surface of the second housing portion.

In certain cases, the one or more secondary capacitive sensor electrodes are formed on the surface of the second housing portion via laser direct structuring.

In some examples, the one or more primary capacitive sensor electrodes are formed on the inner surface of the housing via laser direct structuring.

In another aspect, an earpiece includes a housing that contains an electro-acoustic transducer and electronics for controlling operation of the earpiece. The electronics include a printed circuit board, a primary capacitive sensor including one or more primary capacitive sensor electrodes disposed on an inner surface of the housing, and a secondary capacitive sensor including one or more secondary capacitive sensor electrodes disposed on a surface of the printed circuit board. The electronics also include a controller that is configured to receive input from the primary capacitive sensor to control one or more functions of the earpiece. The controller is further configured to receive input from the secondary capacitive sensor to detect if there is an interfering contact with the earpiece, and, if so, reject input from the capacitive touch interface.

Implementations may include one of the above and/or below features, or any combination thereof.

In some implementations, the housing defines an acoustic module which houses the electro-acoustic transducer, and an electronics module which houses the electronics.

In certain implementations, one or more spring contacts are mounted on a top surface of the printed circuit board. The one or more spring contacts electrically connect the one or more primary capacitive sensor electrodes to the printed circuit board. The one or more secondary capacitive sensor electrodes are disposed on an edge surface of the printed circuit board. The edge surface is arranged orthogonally to the top surface of the printed circuit board.

In some cases, the one or more secondary capacitive sensor electrodes are formed by plating the edge surface of the printed circuit board.

### BRIEF DESCRIPTION OF THE DRAWINGS

FIG. 1 is a view of the lateral surface of the human ear.

FIG. 2A is a perspective view of an earpiece.

FIGS. 2B through 2G are front, rear, left side, right side, top and bottom views, respectively, of the earpiece of FIG. 2A.

FIG. 2H is a sectional view of the earpiece of FIG. 2A taken along line 2H-2H in FIG. 2D.

FIGS. 3A and 3B are perspective views of an internal dividing plate of the earpiece of FIG. 2A.

FIGS. 4A and 4B are perspective views of a third housing portion of the earpiece of FIG. 2A.

FIGS. 5A and 5B are perspective views of a printed circuit board of the earpiece of FIG. 2A.

FIGS. 6A and 6B are perspective views of the printed circuit board of FIG. 5A shown with electrodes from the third housing portion of FIG. 4B.

FIG. 7 is a system diagram illustrating electronics and a connected capacitive touch interface within the earpiece of FIG. 2A.

FIG. 8 is a perspective view of a second housing portion illustrating an alternative location for a secondary capacitive sensor for the earpiece of FIG. 2A.

### DETAILED DESCRIPTION

Commonly labeled components in the FIGURES are considered to be substantially equivalent components for the purposes of illustration, and redundant discussion of those components is omitted for clarity. Numerical ranges and values described according to various implementations are merely examples of such ranges and values and are not intended to be limiting of those implementations. In some cases, the term “about” may be used to modify values, and in these cases, can refer to that value +/− a margin of error, such as a measurement error, which may range from up to 1-5 percent.

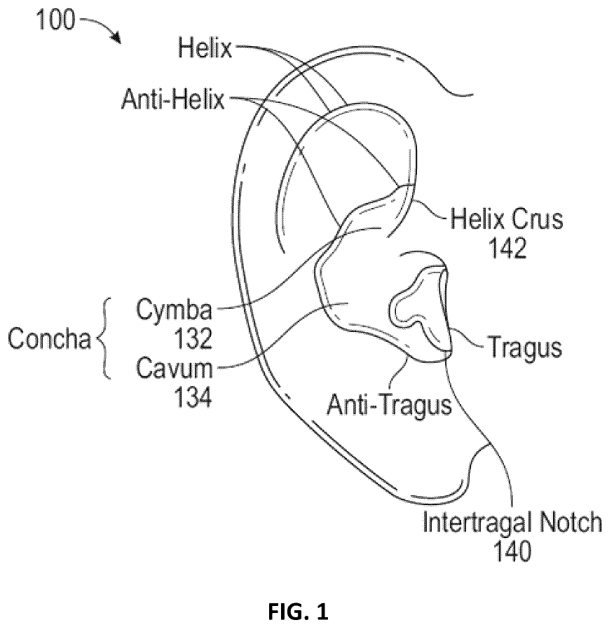

FIG. 1 shows the lateral surface of a human right ear, with some features identified. There are many different ear sizes and geometries. Some ears have additional features that are not shown in FIG. 1. Some ears lack some of the features that are shown in FIG. 1. Some features may be more or less prominent than are shown in FIG. 1.

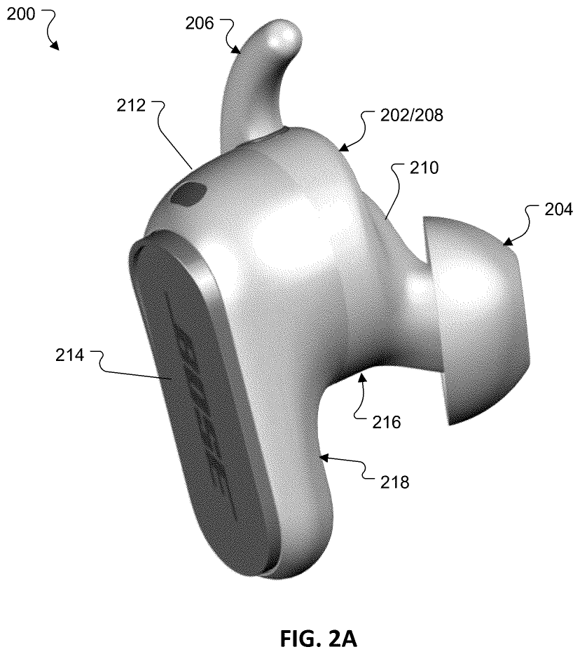

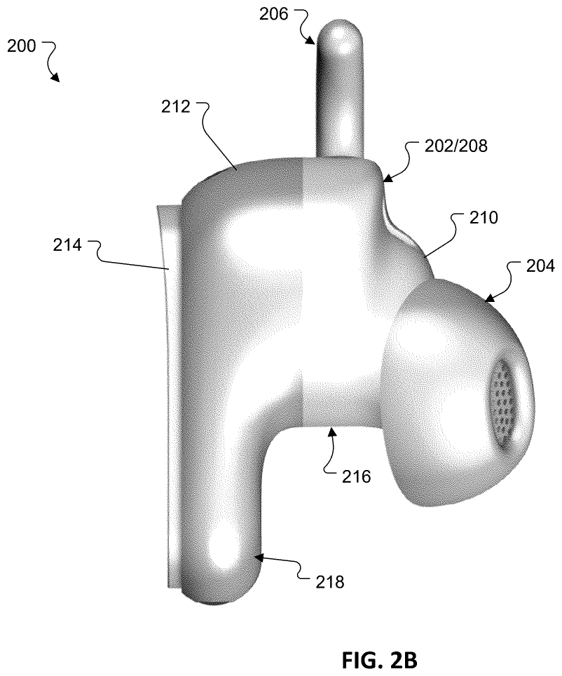

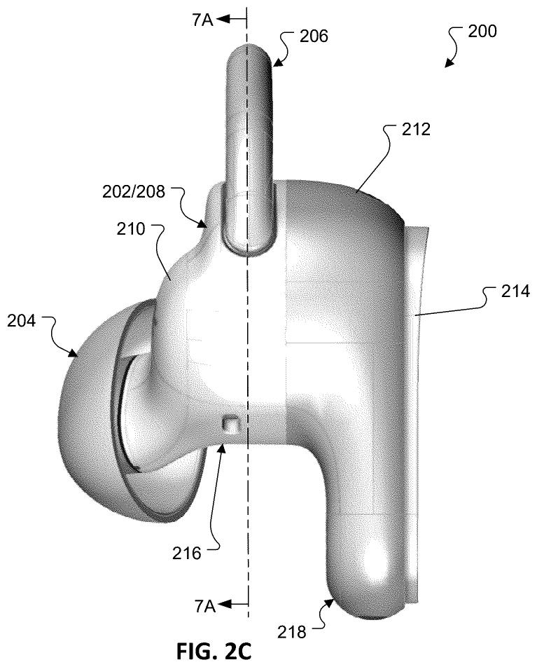

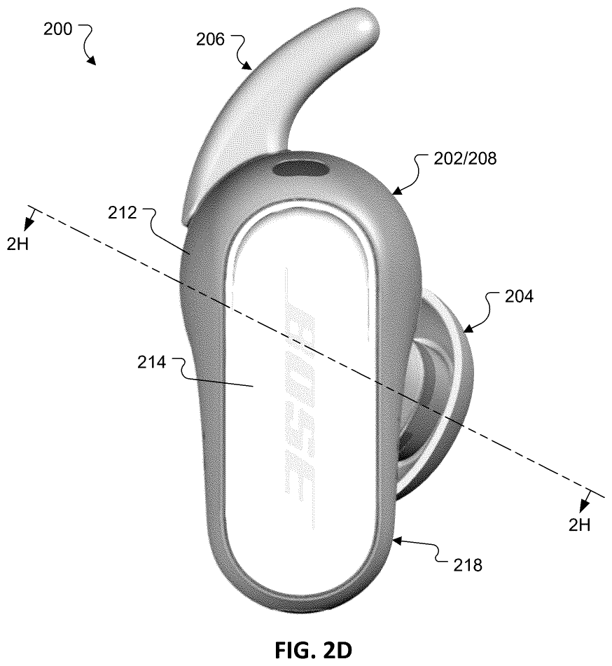

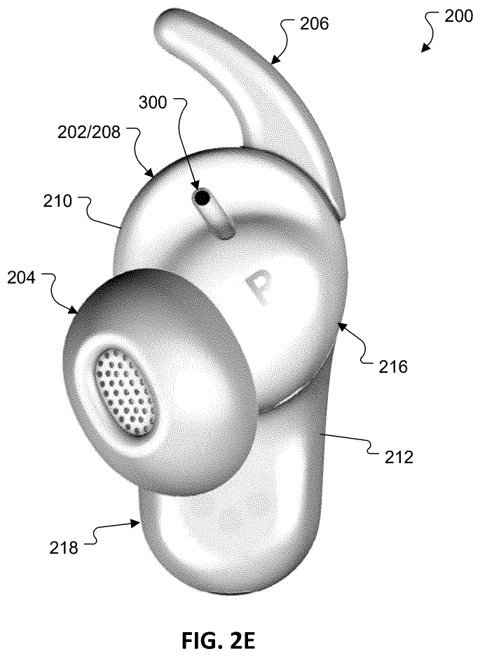

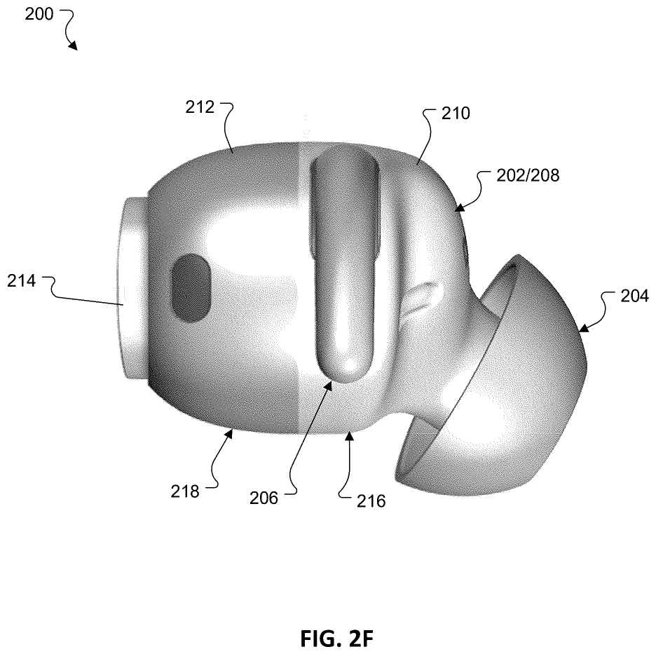

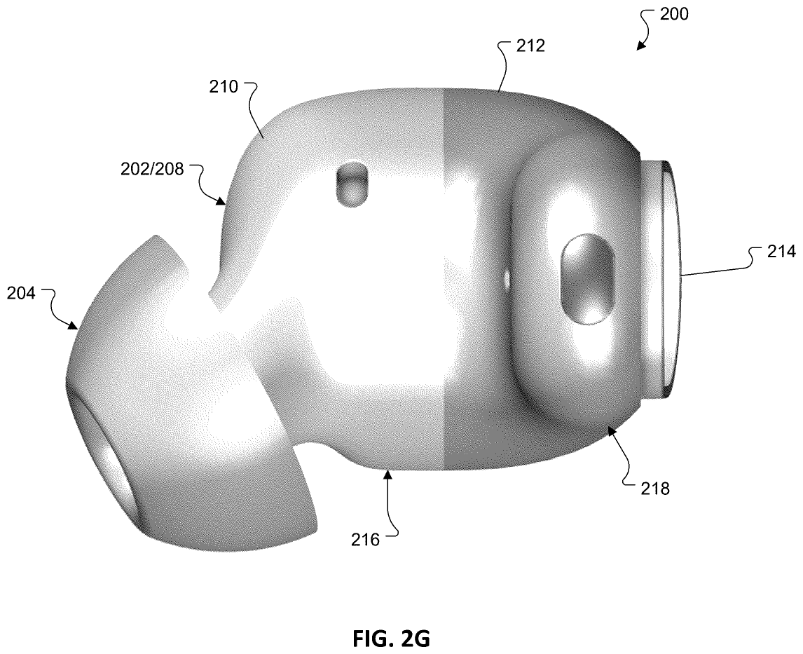

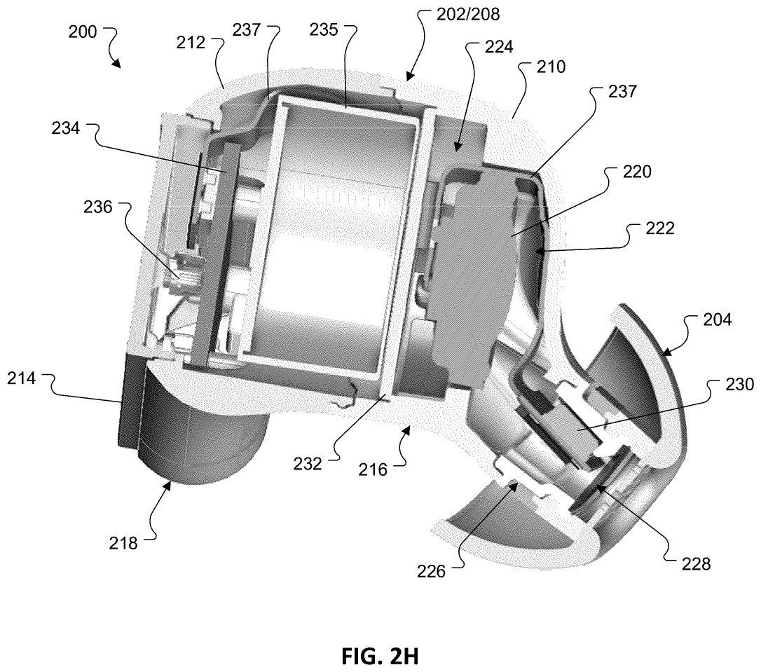

FIGS. 2A-2H illustrate an exemplary earpiece 200 for the right ear of a user. A mirror-image of the design would be used for an earpiece for the left ear. The earpiece 200 includes an earbud 202, an ear tip 204, and a retaining piece 206. The earbud 202 includes a housing 208 having a first housing portion 210, a second housing portion 212, and a third housing portion (cap) 214 that together define an acoustic module 216 and an electronics module 218. The ear tip 204 provides an acoustic seal with a user's ear when the earpiece 200 is used. The retaining piece 206 engages the user's antihelix when the earpiece is worn to assist with retaining the earpiece in the user's ear. The first, second, and third housing portions 210, 212, 214 may be formed of a thermoplastic material(s). Suitable thermoplastic materials include polycarbonate, polybutylene terephthalate (PBT) and polyethylene terephthalate (PET), polycarbonate/acrylonitrile butadiene styrene (PC/ABS), polyamide (nylon), polyether ether ketone (PEEK), or acrylonitrile butadiene styrene (ABS). Such thermoplastic materials may include glass-fill for stiffness. The first, second, and third housing portions 210, 212, 214 may be secured together via an adhesive.

With reference to FIG. 2H, the acoustic module 216 contains/houses an electro-acoustic transducer 220 that divides the acoustic module 216 into a first (front) acoustic cavity 222 and a second (rear) acoustic cavity 224. A first (front) side of the electro-acoustic transducer 220 radiates acoustic energy into the fist acoustic cavity 222 and a second (rear) side of the electro-acoustic transducer 220 radiates acoustic energy into the second acoustic cavity 224. A nozzle 226 is coupled to the housing 208 and is configured to direct acoustic energy from the first acoustic cavity 222 to a nozzle exit opening 228. An exterior surface of the nozzle 226 supports the ear tip 204. In some cases, a microphone 230, e.g., a feedback microphone for feedback noise cancellation, may be located within the nozzle 226. In some cases, the nozzle 226 may be formed integrally with the housing 208. For example, the nozzle 226 may be defined by the first housing portion 210. Alternatively, or additionally, the nozzle 226 may be formed, in whole or in part, as a separate housing portion and may be attached to the first housing portion 210, e.g., via an adhesive.

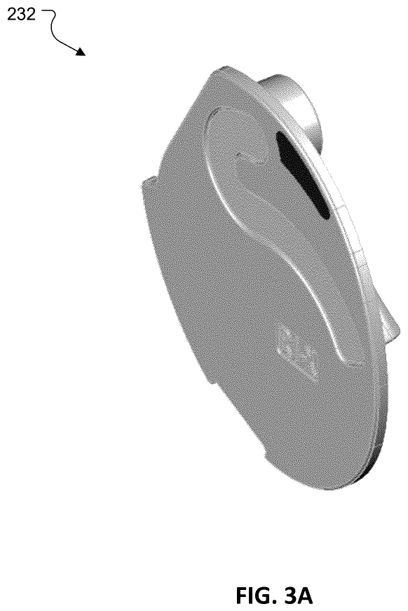

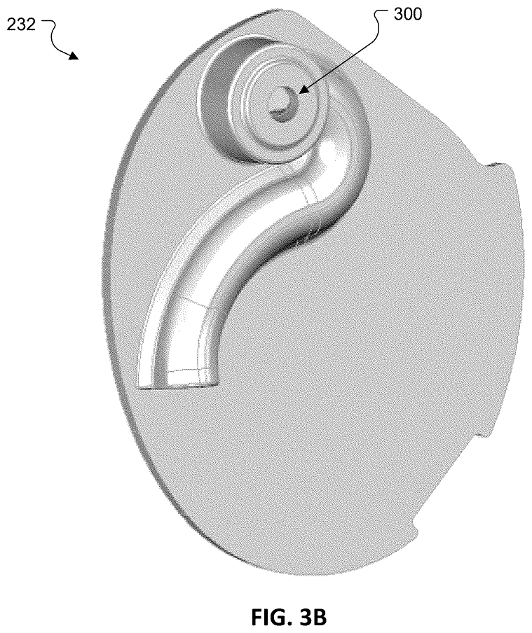

In the illustrated example, an internal dividing plate 232 is arranged between the second acoustic cavity 224 and the electronics module 218 and separates the acoustic module 216 from the electronics module 218. With reference to FIGS. 3A & 3B, the internal dividing plate 232 may also help to define an acoustic port 300 (e.g., a mass port) between the second acoustic cavity 224 and the external environment outside of the housing 208. Additional details regarding the internal dividing plate may be found in U.S. Pat. No. 11,638,081, titled “Earphone Port,” which issued on Apr. 25, 2023. The complete disclosure of U.S. Pat. No. 11,638,081 is incorporated herein by reference.

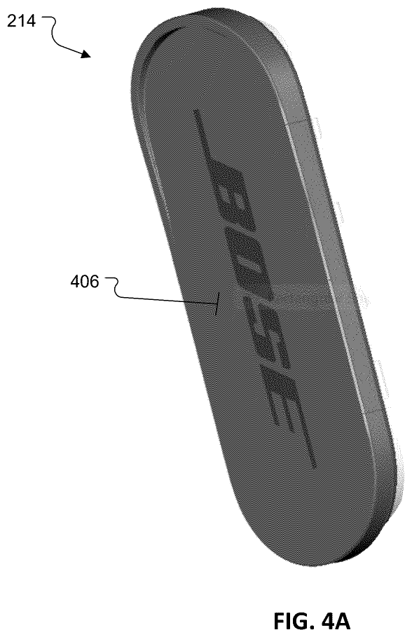

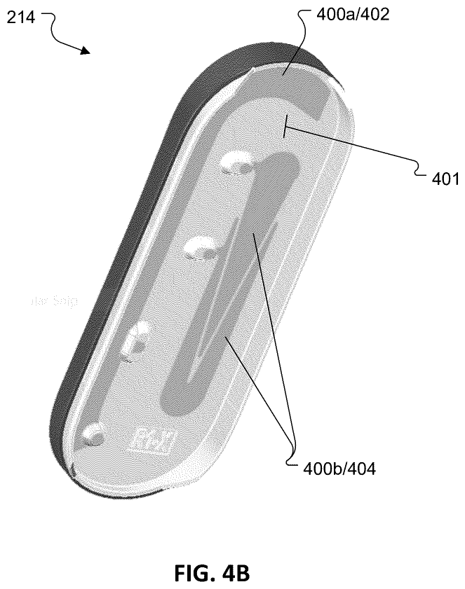

Referring again to FIG. 2H, the electronics module 218 houses electronics for driving the electro-acoustic transducer 220. The electronics include a printed circuit board 234 that may support various electronic components (e.g., microprocessor, wireless transceiver, power management circuitry, digital signal processor (DSP)), a power source (e.g., a battery 235), one or more sensors (e.g., electrode(s) 400b (FIG. 4B) for a primary capacitive sensor 404), one or more electrical connectors, one or more microphones, and wiring (e.g., flexible printed circuitry 237) that electrically connects the electronics together and with the electro-acoustic transducer 220 and feedback microphone.

Referring to FIGS. 4A & 4B, the third housing portion 214 may carry electrically conductive traces 400a, 400b (generally “400”) that may be formed directly on an inner surface 401 of the third housing portion 214 (e.g., via laser direct structuring (LDS)). The traces 400 may form an antenna 402 for wireless communication and/or the traces 400 may form one or more electrodes for the primary capacitive sensor 404. The traces 400 may be electrically connected to the printed circuit board 234 (FIG. 2H) via spring contacts 236 (FIG. 2H) mounted on the printed circuit board 234 that contact the traces 400 when the housing 208 is assembled. Additional details regarding the forming of an antenna or capacitive sensor electrodes using LDS on a cap of a earbud housing can be found in U.S. Pat. No. 11,115,745, titled “Systems and methods for antenna and ground plane mounting schemes for in-ear headphone,” which issued Sep. 7, 2021. The complete disclosure of U.S. Pat. No. 11,115,745 is incorporated herein by reference. The primary capacitive sensor is positioned to receive user input, e.g., for controlling volume, answering phone calls, and/or toggling between active noise reduction (ANR) modes.

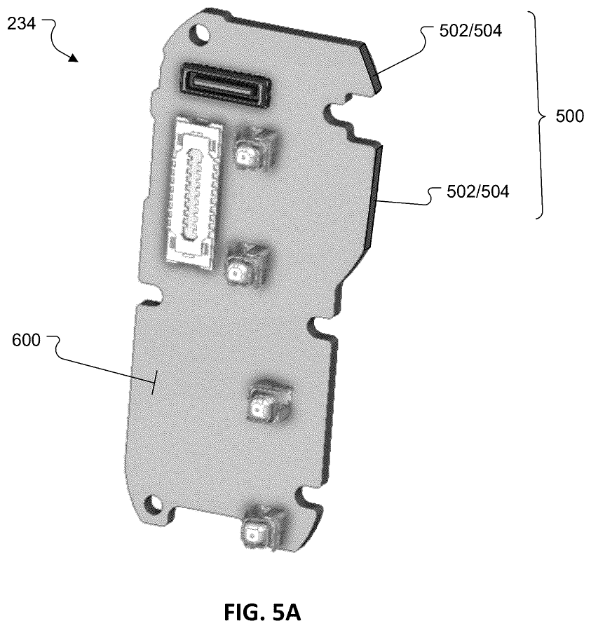

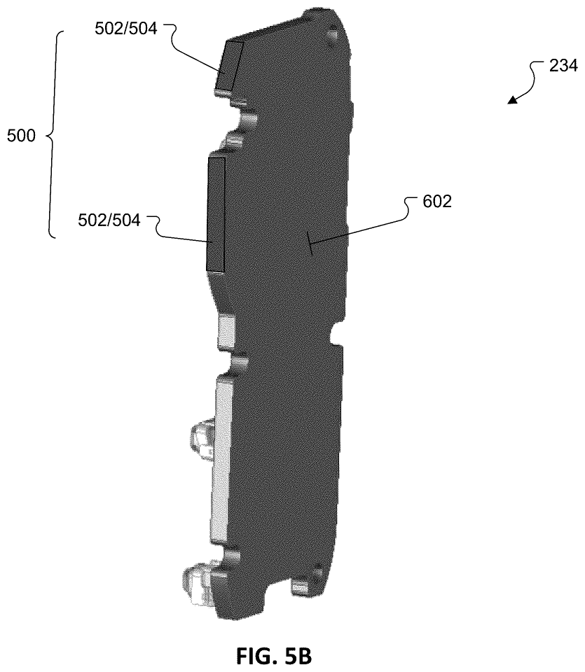

Notably, the printed circuit board supports a second, secondary capacitive sensor 500 (FIG. 5). The secondary capacitive sensor 500 is positioned to detect whether an object (such as the user's hair or a hat) is contacting the side of the earbud, which might otherwise be sensed by the primary capacitive sensor and misinterpreted as user input. When input from the secondary capacitive sensor is indicative that something is touching the side of the earbud, then input from primary capacitive sensor is ignored/rejected.

With reference to FIGS. 5A & 5B, to provide the secondary capacitive sensor 500, one or more regions of an edge surface 502 of the printed circuit board 234 are plated with an electrically conductive material (e.g., copper) to form one or more electrodes 504 (aka “secondary capacitive sensor electrodes”) of the secondary capacitive sensor 500.

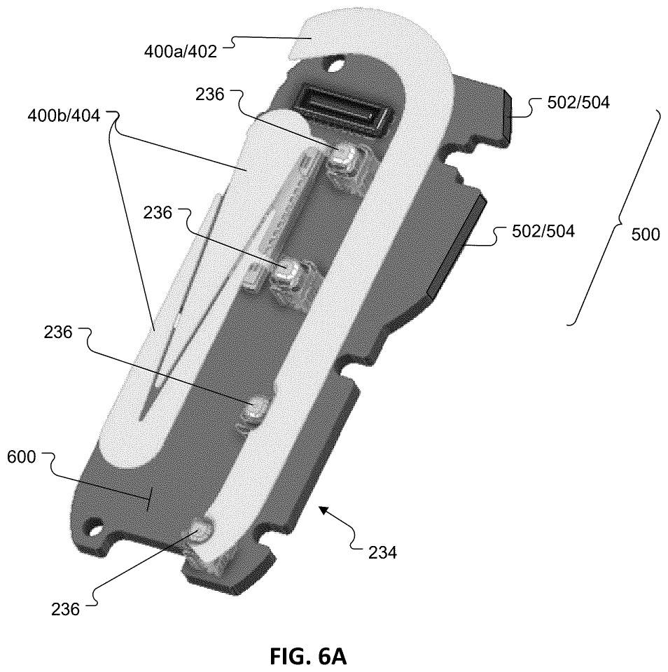

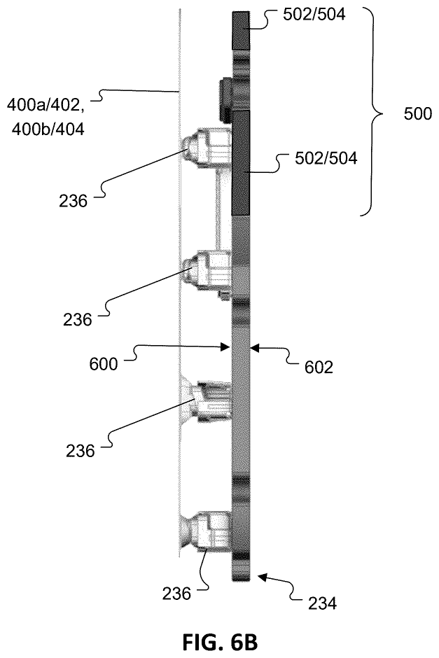

Referring to FIGS. 6A & 6B, a top surface 600 of the printed circuit board 234 lies in a plane that is substantially parallel the inner surface 401 (FIG. 4B) of the third housing portion 214 (FIG. 4B), and, consequently, is arranged substantially parallel to the electrodes 400b of the primary capacitive sensor 404. The edge surface 502 of the printed circuit board 234 is substantially perpendicular to the top surface 600 of the printed circuit board 234 and extends between the top surface 600 and an opposing bottom surface 602, such that the one or more electrodes 504 of the secondary capacitive sensor 500 lie in a plane that is substantially perpendicular to the electrodes 400b of the primary capacitive sensor 404.

The spring contacts 236 mounted on the top surface 600 of the printed circuit board 234 provide an electrical connection between the electrodes 400b of the primary capacitive sensor 404 and the printed circuit board 234 and also provide an electrical connection between the antenna 402 and the printed circuit board 234.

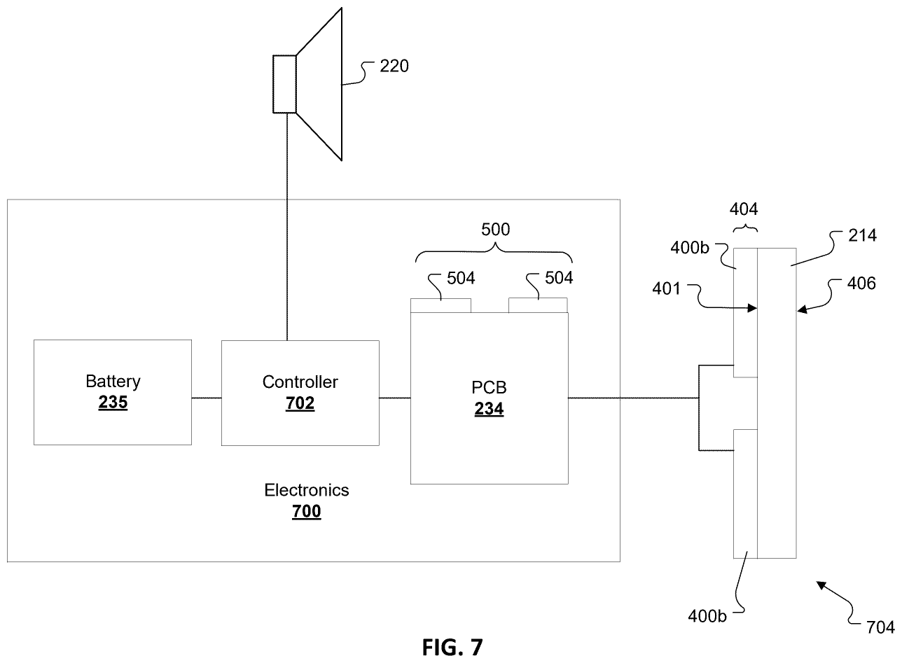

FIG. 7 shows a schematic depiction of the electronics 700 contained (at least partially) within the electronics module 218 (e.g., as shown in FIGS. 2A & 2H) including components of the capacitive touch interface (CTI). It is understood that one or more of the components in electronics may be implemented as hardware and/or software, and that such components may be connected by any conventional means (e.g., hard-wired and/or wireless connection).

As shown in FIG. 7, electronics 700 contained within the electronics module 218 (FIG. 2A) can include a power source (e.g., battery 235) for powering the electro-acoustic transducer 220. The power source 235 is connected with a controller 702, which is configured to perform control functions according to various implementations described herein. Electronics 700 can include other components not specifically depicted in the accompanying FIGURES, such as communications components (e.g., a wireless transceiver (WT)) configured to communicate with one or more other electronic devices connected via one or more wireless networks (e.g., a local WiFi network, Bluetooth connection, or radio frequency (RF) connection), and amplification and signal processing components. It is understood that these components or functional equivalents of these components can be connected with, or form part of, the controller 702.

The controller 702 can include conventional hardware and/or software components for executing program instructions or code according to processes described herein. For example, controller may include one or more processors, memory, communications pathways between components, and/or one or more logic engines for executing program code. The controller 702 can be coupled with other components in the electronics via any conventional wireless and/or hardwired connection which allows controller to send/receive signals to/from those components and control operation thereof.

The controller 702 is shown coupled with the printed circuit board (PCB) 234, which in turn is coupled with a capacitive touch interface 704. The controller 702 may be mounted on a surface of the PCB 234, e.g., the top or bottom surface of the PCB 234. The controller 702 is configured to receive touch-based commands from the capacitive touch interface in order to control operation of the earpiece 200. For example, a user can provide a touch command at the capacitive touch interface in order to power the earpiece on or off, switch between playback sources, switch tracks or segments within a playback source, toggle through a menu of playback options, etc.

The capacitive touch interface 704 is shown including a contact surface 406, e.g., an outer surface of the third housing portion 214 (see also FIG. 4A), for receiving the touch command (e.g., from a user such as a human user), and the primary capacitive sensor electrodes 400b underlying the contact surface 406 (i.e., on the opposing, inner surface 401 of the third housing portion 214) for detecting the touch command at the contact surface 406. Two electrodes 400b are illustrated in FIG. 7, however, it is understood that any number of electrodes greater than (2) can form part of the interface. Electrodes 400b can be connected through the PCB 234 to the controller 702 by one or more via and/or trace connections to an I/O pin coupled with the controller 702. As is known in the art, when a user (e.g., a user's finger) touches the contact surface 406 of a capacitive touch interface 704 (e.g., contact surface of capacitive touch interface), it forms a simple parallel plate capacitor, whose digital value is measured and used to detect presence at the particular electrode and/or movement across electrodes (such as in a swiping motion).

Having two or more electrodes permits detection of movement across the interface, significantly increasing the number of available commands from a single-electrode interface. While conventional capacitive touch interfaces use multiple electrodes to detect movement across an interface, these conventional electrode configurations include electrodes separated from neighboring electrodes by linear borders. That is, these conventional interfaces have electrodes with border profiles that are linear or approximate a linear border.

The one or more electrodes 504 of the secondary capacitive sensor 500 are also connected to the controller 702, e.g., by one or more via and/or trace connections on the PCB 234. The controller 702 is configured to measure capacitance of the secondary capacitive sensor 500 to determine whether an interfering object is touching the side of the earpiece 200 (FIG. 2A), and, if so, rejecting input from the capacitive touch interface 704. This can inhibit unintended input from the capacitive touch interface 704 that occurs as a result of contact with an interfering object, such as the user's hair or a hat, from being misinterpreted as user input.

In some cases, the secondary capacitive sensor 500 may include one electrode and the controller can measure the capacitance of the one secondary capacitive sensor electrode relative to ground. Alternatively, the secondary capacitive sensor may include a pair of secondary capacitive sensor electrodes and the controller can measure the capacitance of one of the electrodes relative to the other.

### Other Implementations

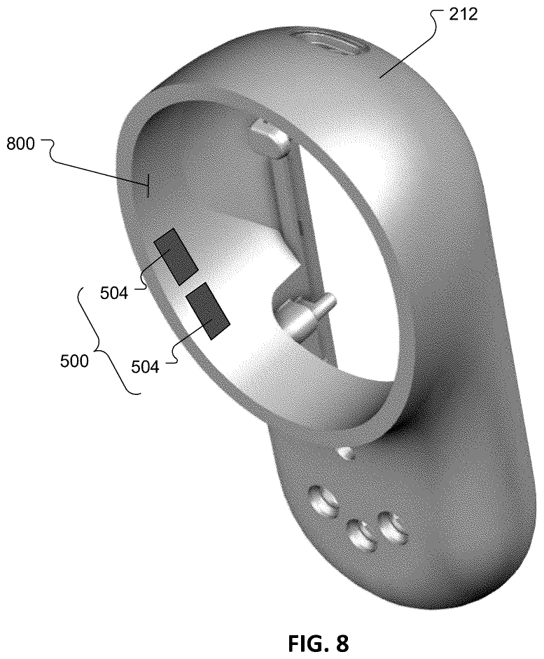

In some implementations, the one or more electrodes 504 of the secondary capacitive sensor 500 may instead be supported on a separate housing piece. For example, as shown in FIG. 8, the secondary capacitive sensor electrode(s) 504 may be formed, e.g., via LDS, on an inner surface 800 of the second housing portion 212.

While implementations have been described in which a housing is made up of three housing portions, other implementations with more or fewer housing portions are contemplated.

Although implementations of an earpiece have been described which include a retaining piece for assisting in retaining the earpiece in a user's ear, other implementations may not include a retaining piece.

While implementations of an earpiece in the form of an in-ear headphone have been described, other implementations are contemplated. For example, in some implementations, the earpiece may have an open ear configuration, such as described in U.S. Pat. No. 11,140,469, titled OPEN-EAR HEADPHONE.

A number of implementations have been described. Nevertheless, it will be understood that additional modifications may be made without departing from the scope of the inventive concepts described herein, and, accordingly, other implementations are within the scope of the following claims.

What is claimed is:

1. An earpiece comprising:
a primary capacitive sensor; and
a secondary capacitive sensor arranged substantially orthogonally to the primary capacitive sensor; and
a controller configured to receive input from the primary capacitive sensor to control one or more functions of the earpiece,
wherein the controller is further configured to receive input from the secondary capacitive sensor to detect if there is an interfering contact with the earpiece, and, if so, reject input from the capacitive touch interface.

2. The earpiece of claim 1, wherein the earpiece comprises a housing, and
wherein the primary capacitive sensor comprises one or more primary capacitive sensor electrodes disposed on an inner surface of the housing.

3. The earpiece of claim 2, wherein the earpiece further comprises a printed circuit board disposed within the housing, and
wherein the secondary capacitive sensor comprises one or more secondary capacitive sensor electrodes disposed on a surface of the printed circuit board.

4. The earpiece of claim 3, wherein the printed circuit board comprises a top surface arranged substantially parallel to the one or more primary capacitive sensor electrodes; a second surface, opposite the first surface; and an edge surface that extends between the top and bottom surfaces, and
wherein the one or more secondary capacitive sensor electrodes are disposed on the edge surface.

5. The earpiece of claim 4, further comprising one or more spring contacts mounted on the top surface of the printed circuit board, wherein the one or more spring contacts provide an electrical connection between the one or more primary capacitive sensor electrodes and the printed circuit board.

6. The earpiece of claim 5, wherein the controller is mounted on the top surface or the bottom surface of the printed circuit board.

7. The earpiece of claim 6, wherein the controller is electrically connected to the one or more spring contacts via one or more electrically conductive traces of the printed circuit board.

8. The earpiece of claim 3, wherein the one or more secondary capacitive sensor electrodes are formed by plating the surface of the printed circuit board.

9. The earpiece of claim 2, wherein the housing comprises:
a first housing portion that at least partially defines an acoustic module that houses an electro-acoustic transducer;
a second housing portion that at least partially defines an electronics module that houses electronics for driving the electro-acoustic transducer, and
a third housing portion,
wherein the one or more primary capacitive sensor electrodes are disposed on the third housing portion.

10. The earpiece of claim 9, wherein the secondary capacitive sensor comprises one or more secondary capacitive sensor electrodes disposed on a surface of the second housing portion.

11. The earpiece claim 10, wherein the one or more secondary capacitive sensor electrodes are formed on the surface of the second housing portion via laser direct structuring.

12. The earpiece of claim 2, wherein the one or more primary capacitive sensor electrodes are formed on the inner surface of the housing via laser direct structuring.

13. An earpiece, comprising:
a housing containing:
an electro-acoustic transducer; and
electronics for controlling operation of the earpiece, the electronics comprising:
a printed circuit board,
a primary capacitive sensor comprising one or more primary capacitive sensor electrodes disposed on an inner surface of the housing,
a secondary capacitive sensor comprising one or more secondary capacitive sensor electrodes disposed on a surface of the printed circuit board, and
a controller configured to receive input from the primary capacitive sensor to control one or more functions of the earpiece,
wherein the controller is further configured to receive input from the secondary capacitive sensor to detect if there is an interfering contact with the earpiece, and, if so, reject input from the capacitive touch interface.

14. The earpiece of claim 13, wherein the housing defines an acoustic module which houses the electro-acoustic transducer, and an electronics module which houses the electronics.

15. The earpiece of claim 13, further comprising one or more spring contacts mounted on a top surface of the printed circuit board, wherein the one or more spring contacts electrically connect the one or more primary capacitive sensor electrodes to the printed circuit board,
wherein the one or more secondary capacitive sensor electrodes are disposed on an edge surface of the printed circuit board, the edge surface being arranged orthogonally to the top surface of the printed circuit board.

16. The earpiece of claim 15, wherein the one or more secondary capacitive sensor electrodes are formed by plating the edge surface of the printed circuit board.
